(19) United States
(12) Patent Application Publication
(10) Pub. No.: US 2005/0085060 A1
(43) Pub. Date: Apr. 21, 2005

(54) Self-aligned silicide process for preventing electrical shorts

(76) Inventors: Been Jon Woo, Shanghai (CN); Julian Chang, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/967,173

(22) Filed: Oct. 19, 2004

(30) Foreign Application Priority Data
Oct. 21, 2003 (CN) 200310108056.0

(51) Int. Cl. H01L 21/336; H01L 21/3205; H01L 21/4763

(52) U.S. Cl. 438/592

(57) ABSTRACT

A self-aligned silicide process for preventing electrical shorts which is applied on a semiconductor structure. A surface of the semiconductor structure is provided, having a conductive area and an insulation area. A protection structure is formed therebetween by implanting silicon or germanium and depositing a thin layer of titanium, which prevents the formation of native oxide. The device is completed by forming salicide on the conductive area.

### FIELD OF THE INVENTION

The present invention relates generally to a self-aligned silicide process, and more specifically, a self-aligned silicide process for preventing electrical shorts.

### DESCRIPTION OF THE PRIOR ART

As semiconductor devices shrink to a size with sub-micron or deep sub-micron features, numerous problems occur, such as the increase in sheet resistance. In order to overcome this problem, self-aligned silicide (salicide) is applied in semiconductor fabrication processing.

The fabrication process of self-aligned silicide involves metal deposition not reacting with silicon oxide, silicon nitride, or silicon oxynitride. The metal applied in the self-aligned silicide process comprises Pt (platinum), Ti (titanium), Ni(Nickel) or Co(Cobalt). Each of these metals can react with silicon to form a low resistivity phase, such as PtSi₂, TiSi₂, NiSi, or CoSi₂. In metal oxide semiconductor fabrication processing, metal deposition is carried out after forming the source/drain junction. In general, before metal deposition, the oxide on the semiconductor device is removed. An in-situ argon (Ar) sputter etch is often used to remove the oxide.

However, sputter over-etching can occur on spacers between the gate and source/drain and on the top of the semiconductor device resulting in electrical shorts.

### SUMMARY OF THE INVENTION

The present invention provides a self-aligned silicide process for preventing electrical shorts and for preventing the re-deposition of silicon due to over-sputter etching.

The present invention also provides a self-aligned silicide process for suppressing the formation of oxide by doping the semiconductor material or depositing a thin layer of metal.

In accordance with the present invention, a self-aligned silicide process, applied on a semiconductor structure, is described. A surface of the semiconductor structure, having a conductive area and an insulation area, is provided. A protection structure is formed thereon by implanting, for example, silicon or germanium, or by depositing a thin layer of metal such as titanium, that prevents the formation of an oxide layer. The silicide is formed on the conductive area.

This invention has been summarized above and described with reference to the preferred embodiments. Some processing details have been omitted and are understood by those skilled in the art. More details of this invention are stated in the description of the preferred embodiments section.

### BRIEF DESCRIPTION OF THE DRAWINGS

These and other objects, features and advantages of the present invention can best be understood by reference to the detailed description of the preferred embodiments set forth below taken with the drawings, in which:

FIG. 1 and FIG. 2 show a cross-sectional view of a semiconductor structure in accordance with embodiments of the present invention.

### DESCRIPTION OF THE PREFERRED EMBODIMENTS

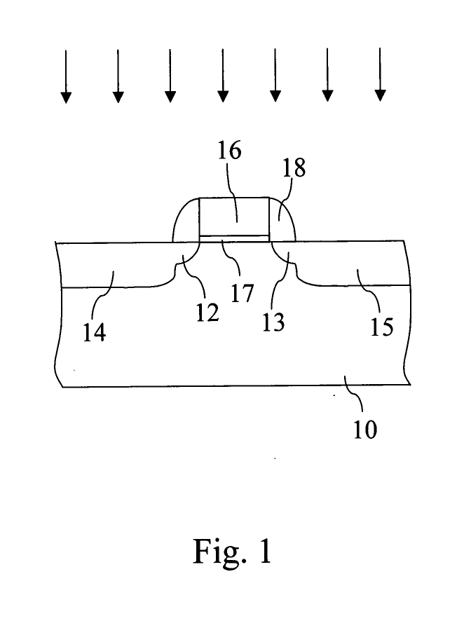

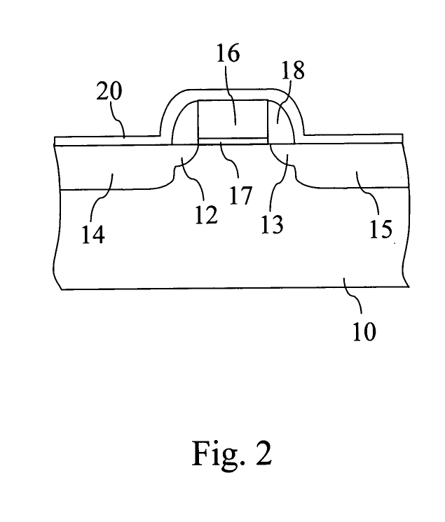

Referring now to FIGS. 1 and 2, a cross-sectional view of a semiconductor structure is shown. A semiconductor structure comprising a semiconductor substrate 10 is provided. First doped areas 12 and 13 and second doped areas 14 and 15 are formed on the surface of the semiconductor substrate 10. A gate structure, having a gate electrode 16 and spacers 18 on the sidewalls of the gate electrode 16, is also provided. The gate electrode 16 and the spacers 18 are formed on the surface of the semiconductor substrate 10. The semiconductor substrate 10 is a silicon wafer, for example, a monocrystalline Si wafer or epitaxial Si-containing substrate. The first doped areas 12 and 13 is for example, doped N-type or P-type areas, such as lightly doped drains (LDD). The second doped areas 14 and 15 are respectively on two sides of the first doped areas 12 and 13. The second doped areas 14 and 15, are for example, doped N type or P type areas, such as source/drain areas. The gate electrode 16, is for example a conductively doped or non-doped polysilicon layer. The spacers 18 are formed of an insulating material, such as silicon oxide or silicon nitride.

The gate structure further comprises other portions, such as a gate oxide 17. Moreover, the spacers 18 may also comprise multi-insulation layers, but are typically limited to a single insulating material. In the present invention for such a semiconductor structure, the surface comprises a conductive area and an insulation area, such as the gate electrode 16 and the second doped areas 14 and 15, and the surface of the spacers 18. It should be noted that, for other semiconductor structures which are not shown, whether multi-layered or single layer, if only the surface is formed of a conductive material or semiconductor material, it can be the conductive area of the present invention. Also, if only the surface is formed of an insulating material or low-k dielectric material, it can be the insulation area of the present invention.

Next, conductive particles, for example silicon or germanium are blanket are implanted into the device and into the conductive area and the insulation area.

Following, a protection layer 20 is formed on the conductive area and the insulation area by depositing a thin layer of a material such as titanium. The thin layer of titanium is formed as an underlayer.

After the protective layer 20 is formed, metal is deposited and annealed to form salicide.

The conductive particle implantation and protective layer 20 prevent the formation of native oxide. Another feature of the present invention is that, the protection layer 20 formed by implanting conductive particles and depositing a thin layer of titanium also prevents a decrease of salicide, such as the defect formation of interdiffusion of silicon and cobalt during the formation of cobalt silicon.

Using the semiconductor structure of the present invention prevents the formation of native oxide, and not only decreases the amount of etchant in the argon sputter etch but also the temperature during the formation of salicide, which enables the self-aligned suicide process to be easily controlled.

While the invention has been particularly shown and described with reference to the preferred embodiments thereof, it will be understood by those skilled in the art that various changes in form and details may be made without departing from the spirit and scope of the invention.

1. A self-aligned silicide process for preventing electrical shorts comprising:
providing a semiconductor structure having a conductive area and an insulation area;
forming a protection structure on the conductive area and the insulation area for preventing the formation of native oxide; and
forming a salicide on the conductive area.

2. The self-aligned silicide process of claim 1, wherein forming the protection structure comprises implanting silicon into the conductive area and the insulation area by blanket implanting.

3. The self-aligned silicide process of claim 1, wherein forming the protection structure comprises implanting germanium into the conductive area and the insulation area by blanket implanting.

4. The self-aligned silicide process of claim 1, wherein forming the protection structure comprises forming a thin layer of titanium on the conductive area and the insulation area.

5. The self-aligned silicide process of claim 1, wherein the conductive area comprises a gate electrode.

6. The self-aligned silicide process of claim 1, wherein the insulation area comprises a silicon nitride spacer.

7. The self-aligned silicide process of claim 1, wherein the conductive area comprises a source/drain area.

8. The self-aligned silicide process of claim 1, wherein forming the salicide on the conductive area comprises forming a cobalt silicide layer.

9. A self-aligned silicide process for preventing electrical shorts comprising:
providing a semiconductor structure having a conductive area and an insulation area;
implanting at least one semiconductor particle into the conductive area and the insulation area by blanket implanting;
forming a thin layer of titanium on the conductive area and the insulation area; and
forming a salicide on the conductive area.

10. The self-aligned suicide process of claim 9, wherein the semiconductor particle comprises silicon.

11. The self-aligned silicide process of claim 9, wherein the semiconductor particle comprises germanium.

12. The self-aligned silicide process of claim 9, wherein the conductive area comprises a gate electrode.

13. The self-aligned silicide process of claim 9, wherein the insulation area comprises a silicon nitride spacer.

14. The self-aligned silicide process of claim 9, wherein the conductive area comprises a source/drain area.

15. The self-aligned silicide process of claim 9, wherein
forming the salicide on the conductive area comprises
forming a cobalt silicide layer

16. A self-aligned silicide process for preventing electrical shortscomprising:
providing a semiconductor structure having a conductive area and an insulation area;
blanket implanting semiconductor particles into the conductive are and the insulation area;
forming a titanium protective layer on the conductive area and the insulation area;
depositing a metal layer over the titanium protective layer; and
forming a salicide on the conductive area.

17. The self-aligned silicide process of claim 16, wherein the conductive area comprises a gate electrode.

18. The self-aligned silicide process of claim 17, wherein the insulation area comprises a silicon nitride spacer.

19. The self-aligned silicide process of claim 16, wherein the conductive area comprises a source/drain area.

20. The self-aligned silicide process of claim 16, wherein forming the salicide on the conductive area comprises forming a cobalt silicide layer.
